(19) United States
(12) Patent Application Publication
(10) Pub. No.: US 2026/0094260 A1
(43) Pub. Date: Apr. 2, 2026

(54) METHOD FOR ESTIMATING CAUSE OF DEFECTS IN SEMICONDUCTOR WAFERS

(71) Applicant: SAMSUNG ELECTRONICS CO., LTD., Suwon-si (KR)

(72) Inventors: Soohan Kang, Suwon-si (KR); Jaeho Kwak, Suwon-si (KR); Euiseok Kum, Suwon-si (KR); Do-Young Kim, Suwon-si (KR); Dongjoo Moon, Suwon-si (KR); Yoonsung Bae, Suwon-si (KR); Myungho Jung, Suwon-si (KR); Yohwan Joo, Suwon-si (KR)

(21) Appl. No.: 19/088,631

(22) Filed: Mar. 24, 2025

(30) Foreign Application Priority Data
Oct. 2, 2024 (KR) 10-2024-0133775

(51) Int. Cl. G06T 7/00; G06T 7/12; G06V 10/74; G06V 10/75; G06V 10/774; H01L 21/67

(52) U.S. Cl. CPC G06T 7/001; G06T 7/12; G06V 10/759; G06V 10/761; G06V 10/774; H10P 72/0616; G06T 2207/20081; G06T 2207/30148

(57) ABSTRACT

The present disclosure relates to methods for estimating a cause of a defect in a semiconductor wafer. An example method includes acquiring contact model images including information of contact surfaces between manufacturing equipment and a wafer, receiving a defect image including defect information of a target wafer, generating, based on the contact model images and the defect image, partial representations of the contact model images that represent parts associated with the defect information, and determining, from the manufacturing equipment, suspicious equipment estimated to have caused the defect in the target wafer based on the defect image and the partial representations of the contact model images.

### CROSS REFERENCE TO RELATED APPLICATION

This application claims priority to Korean Patent Application No. 10-2024-0133775, filed in the Korean Intellectual Property Office on Oct. 2, 2024, the entire contents of which are hereby incorporated by reference.

### BACKGROUND

The semiconductor manufacturing process becomes more advanced, and along with this, various defect issues have appeared in the semiconductor wafers. In particular, with the introduction of backside process techniques such as Back Side Power Delivery Network (BSPDN), there is growing concern about defects on the backside and frontside of the wafer.

Defects occurring in the semiconductor wafers can significantly reduce yield, and yield is the important factor that determines product quality and manufacturing cost. Therefore, detecting defects in the semiconductor wafers, as well as identifying and resolving the cause of the defects, are important to maintain high yields and ensure an efficient manufacturing process.

### SUMMARY

In order to solve one or more problems (e.g., the problems described above and/or other problems not explicitly described herein), the present disclosure relates to a defect cause estimation method for determining suspicious equipment estimated to have caused the defect in the semiconductor wafer with high accuracy.

An object to be achieved by the present disclosure is not limited to the above, and other objects not mentioned may be clearly understood by those skilled in the art from the description of the present disclosure.

In some implementations, a method for estimating a cause of a defect in a semiconductor wafer may be performed by at least one processor and may include acquiring contact model images including information on contact surfaces between pieces of manufacturing equipment and a wafer, receiving a defect image including defect information of a target wafer, generating, based on the contact model images and the defect image, partial representations of the contact model images representing parts associated with the defect information, and determining, from among the pieces of manufacturing equipment, suspicious equipment estimated to have caused the defect in the target wafer based on the defect image and the partial representations of the contact model images.

In some implementations, a method for estimating a cause of a defect in a semiconductor wafer may be performed by at least one processor and may include acquiring contact model images including information on contact surfaces between pieces of manufacturing equipment and a wafer, receiving a defect image in which defect information of a target wafer is represented in the form of dots, generating a converted defect image by converting the defect information represented in the form of dots into a form of a plane, and determining, from among the pieces of manufacturing equipment, suspicious equipment estimated to have caused the defect in the target wafer by comparing each of the contact model images with the converted defect image.

In some implementations, a method for estimating a cause of a defect in a semiconductor wafer may be performed by at least one processor and may include acquiring contact model images including information on contact surfaces between pieces of manufacturing equipment and a backside of a wafer; receiving a defect image in which defect information of a backside of a target wafer is represented in the form of dots, generating, based on the contact model images and the defect image, partial representations of the contact model images representing parts associated with the defect information, generating a converted defect image by converting the defect information represented in the form of dots into a form of a plane, and determining, from among the pieces of manufacturing equipment, suspicious equipment estimated to have caused the defect in the backside of the target wafer by comparing each of the partial representations of the contact model images with the converted defect image.

In some implementations, if a defect occurs only in a part of the wafer, the estimation accuracy of the suspicious equipment can be improved by comparing the partial representation of the contact model image representing the part associated with the defect information included in the defect image with the defect image, instead of comparing the entire contact model image representing the entire contact region between the manufacturing equipment and the wafer.

In some implementations, the estimation accuracy can be improved by transforming the form of the defect information included in the defect images to be similar to the form of the information of the contact surface included in the contact model images and by using the result for estimation of the suspicious equipment.

The effects that can be obtained through the present disclosure are not limited to those described above. Technical effects not mentioned will be clearly understood by those skilled in the art from the description of the present disclosure described below.

### BRIEF DESCRIPTION OF THE DRAWINGS

The above and other objects, features and advantages of the present disclosure will become more apparent to those of ordinary skill in the art by describing in detail example aspects thereof with reference to the accompanying drawings.

FIG. 1 is a block diagram of an example of an estimation system.

FIG. 2 is a block diagram of an example of a method for estimating a cause of a defect in a semiconductor wafer.

FIG. 3 is a block diagram of an example of a method for estimating a cause of a defect in a semiconductor wafer.

FIG. 4 is a block diagram of an example of a method for estimating a cause of a defect in a semiconductor wafer.

FIG. 5 is a diagram illustrating an example of contact model images.

FIG. 6 is a diagram illustrating an example of a defect image.

FIG. 7 is a diagram of an example of a method for generating partial representations of contact model images.

FIGS. 8 and 9 are example diagrams of a method for generating partial representations of contact model images.

FIGS. 10 and 11 are example diagrams of a method for generating a converted defect image.

FIG. 12 is a flowchart of an example of a method for estimating a cause of a defect in a semiconductor wafer.

FIG. 13 is a flowchart of an example of a method for estimating a cause of a defect in a semiconductor wafer.

FIG. 14 is a flowchart of an example of a method for estimating a cause of a defect in a semiconductor wafer.

FIG. 15 is a block diagram of an example of a defect cause estimation system.

### DETAILED DESCRIPTION

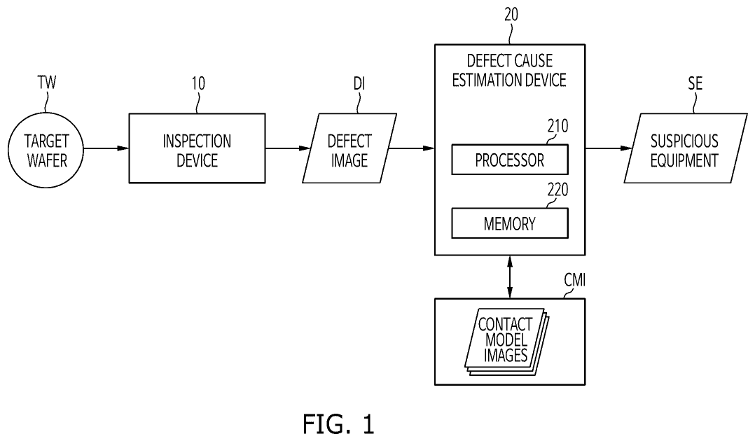

Hereinafter, various examples of the present disclosure will be described with reference to FIGS. 1 to 15. Throughout the description, the same reference numerals may refer to the same components.

FIG. 1 is a block diagram of an example of an estimation system.

Referring to FIG. 1, the estimation system may include an inspection device 10 and a defect cause estimation device 20. The estimation system may detect a defect occurred in a target wafer TW and determine, from among pieces of manufacturing equipment, suspicious equipment SE estimated to have caused the defect in the target wafer TW. The pieces of manufacturing equipment as candidates of the suspicious equipment SE may be pieces of manufacturing equipment that come into contact with the wafer during the manufacturing process.

The defect may be a defect in the backside of the target wafer TW. For example, the defect may include attachment of foreign substances or physical damage/deformation on the backside of the target wafer TW. The defect may be caused by various factors such as dust (particles) introduced from the outside, abnormalities in the processing equipment, by-products generated during the process, thermal effects, physical contact, etc. The pieces of manufacturing equipment as candidates of the suspicious equipment SE may be pieces of manufacturing equipment that come into contact with the backside of the wafer during the manufacturing process. For example, the pieces of manufacturing equipment as candidates of the suspicious equipment SE may include, but are not limited to, transfer robots, Equipment Front End Module (EFEM) robots, chambers, buffers, aligners, etc.

The inspection device 10 may capture an image of the target wafer TW to detect a defect occurring in the target wafer TW. For example, the inspection device 10 may inspect the backside of the target wafer TW using optical equipment (e.g., a laser scanning device), and detect the defect included in the target wafer TW based on the inspection results. The inspection device 10 may capture an image of the target wafer TW so as to acquire a defect image DI including defect information of the target wafer TW. The defect image DI acquired by the inspection device 10 may be transmitted to the defect cause estimation device 20.

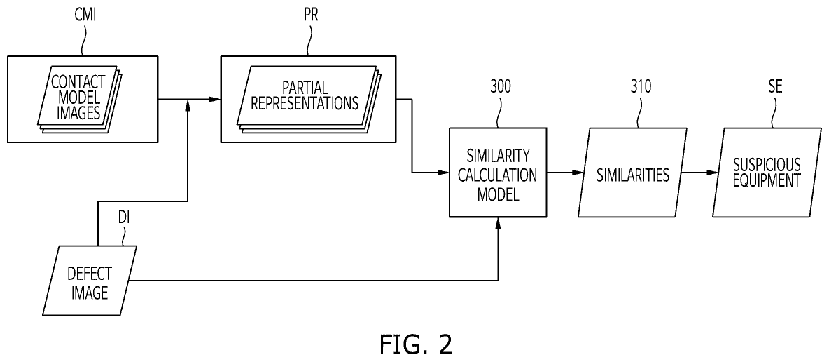

Based on the defect image DI, the defect cause estimation device 20 may determine, from among the pieces of manufacturing equipment, suspicious equipment SE estimated to have caused the defect in the target wafer TW. The defect cause estimation device 20 may determine suspicious equipment SE estimated to have caused the defect in the target wafer TW based on contact model images CMI including information on contact surfaces between the pieces of manufacturing equipment and the wafer (e.g., the backside of the wafer), and the defect images DI. Details of the method of the defect cause estimation device 20 for determining the suspicious equipment SE estimated to have caused the defect in the target wafer TW based on the defect image DI will be described with reference to FIGS. 2 to 14. For the suspicious equipment SE, additional investigation and analysis for resolving the cause of the defect may be performed through the defect cause estimation device 20 and/or an external device.

The defect cause estimation device 20 may include a processor 210 and a memory 220. For example, the defect cause estimation device 20 may be a computing system such as a personal computer, a mobile phone, a server, etc., a module with a plurality of processing cores and memories mounted on a substrate as independent packages, or a system-on-chip (SoC) with a plurality of processing cores and memories embedded in one chip.

The processor 210 may communicate with the memory 220 and execute instructions. In some aspects, the processor 210 may execute a program stored in the memory 220. The program may include a series of instructions. The processor 210 may be any hardware that is capable of independently executing instructions, and may be referred to as, for example, an application processor (AP), a communication processor (CP), a central processing unit (CPU), a graphic processing unit (GPU), a processor core, etc.

The processor 210 and the memory 220 may communicate with each other. The memory 220 may be accessible to the processor 210 and may store software elements that may be executed by the processor 210. The software element may include, as a non-limiting example, a software component, program, application, computer program, application program, system program, software developing program, machine program, operating system (OS) software, middleware, firmware, software module, routine, subroutine, function, method, procedure, software interface, application program interface (API), instruction set, computing code, computer code, code segment, computer code segment, word, value, symbol, or a combination of two or more of these.

The memory 220 may be any hardware that is capable of storing information and accessible to the processor 210. For example, the memory 220 may be a read only memory (ROM), a random-access memory (RAM), a dynamic random access memory (DRAM), a double-data-rate dynamic random access memory (DDR-DRAM), a synchronous dynamic random access memory (SDRAM), a static random access memory (SRAM), a magneto resistive random access memory (MRAM), a programmable read only memory (PROM), an erasable programmable read only memory (EPROM), a flash memory, a polymer memory, a phase change memory, a ferroelectric memory, a silicon-oxide-nitride-oxide-silicon (SONOS) memory, a magnetic card/disk, optical card/disk, or a combination of two or more of the foregoing.

Instructions for performing the defect cause estimation method may be stored in a computer-readable non-transitory storage medium. The term “computer-readable medium” may include any type of medium that may be accessible to a computer, such as a read only memory (ROM), a random access memory (RAM), a hard disk drive, a compact disk (CD), a digital video disk (DVD), or any other type of memory. A “non-transitory” computer-readable medium may exclude wired, wireless, optical, or other communication links that transmit temporary electric or other signals, and may include a medium in which data may be stored permanently, and a medium such as a rewritable optical disk or a removable memory device in which data may be stored and overwritten later.

FIG. 2 is a block diagram of an example of a method for estimating a cause of a defect in a semiconductor wafer.

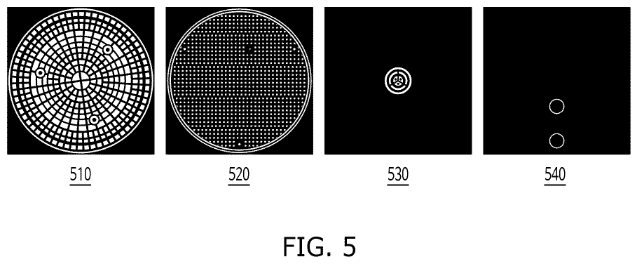

The defect cause estimation device (or processor) may acquire contact model images CMI including information on the contact surfaces between the pieces of manufacturing equipment and the wafer. For example, the contact model images CMI may include information on parts of the pieces of manufacturing equipment coming into contact with the backsides of the wafers. A detailed example of the contact model images CMI will be described below with reference to FIG. 5.

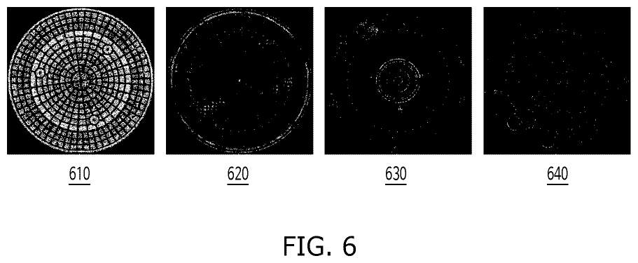

In addition, the defect cause estimation device may receive a defect image DI including defect information of the target wafer. For example, the defect image DI may be an image in which the defect information of the backside of the target wafer is represented in the form of dots. A detailed example of the defect image DI will be described below with reference to FIG. 6.

The defect cause estimation device may generate a partial representation PR of each of the contact model images CMI based on the contact model images CMI and the defect image DI. The partial representation PR of the contact model image CMI may be an image representing a part of the information on the contact surface included in the contact model image CMI that is associated with the defect information included in the defect image DI.

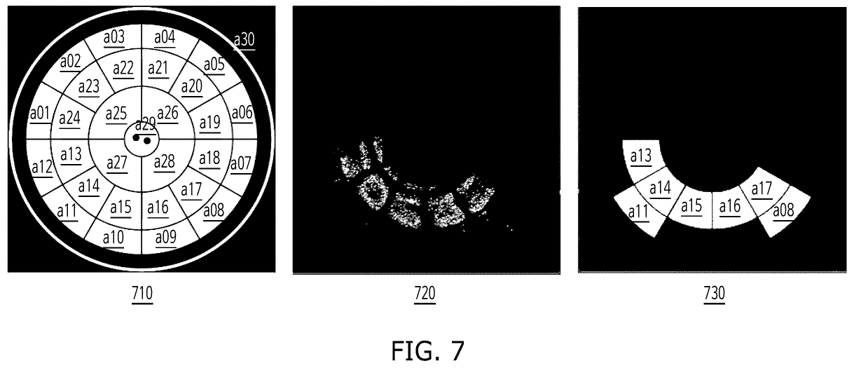

The defect cause estimation device may generate the partial representation PR of each contact model image CMI based on the contact model images CMI and the defect image DI, by extracting the parts associated with the defect information included in the defect image DI of each contact model image CMI. Additionally or alternatively, the defect cause estimation device may generate partial representations PR of the contact model images CMI based on the contact model images CMI and the defect image DI, by using a partial representation generation model. Detailed examples of the method for generating the partial representations PR of the contact model images CMI will be described below with reference to FIGS. 7 to 9.

The defect cause estimation device may determine, from among the pieces of manufacturing equipment, suspicious equipment SE estimated to have caused the defect in the target wafer, based on the partial representation PR of the defect image DI and the contact model images CMI.

For example, first, the defect cause estimation device may calculate a similarity 310 between the partial representation PR of each contact model image CMI and the defect image DI using a similarity calculation model 300. For the similarity calculation model 300, a pixel-by-pixel comparison-based similarity calculation model (e.g., a mean squared error (MSE) calculation model or a histogram comparison-based similarity calculation model (e.g., a histogram bin-based calculation model, etc.) may be used, but aspects are not limited thereto, and any similarity calculation model for calculating the similarity 310 between two images may be used.

The defect cause estimation device may determine the suspicious equipment SE based on the calculated similarity 310. As a specific example, one piece of manufacturing equipment associated with one of the contact model images CMI having the highest similarity 310 to the defect image DI may be determined as the suspicious equipment SE. As another specific example, pieces of manufacturing equipment associated with the contact model images CMI that are within a predetermined ranking (e.g., 5th place) among the contact model images CMI based on their similarities 310 to the defect image DI may be determined as pieces of suspicious equipment SE (or a suspicious equipment group). For a piece of manufacturing equipment (or pieces of manufacturing equipment) determined as the suspicious equipment SE, additional investigation and analysis for resolving the cause of the defect may be performed through the defect cause estimation device and/or an external device.

According to some aspects, when the defect occurs only on a part of the wafer, the accuracy of the estimation of the suspicious equipment SE can be improved by comparing the partial representation PR of the contact model image CMI representing a part associated with the defect information included in the defect image DI with the defect image DI, instead of comparing the entire contact model image CMI.

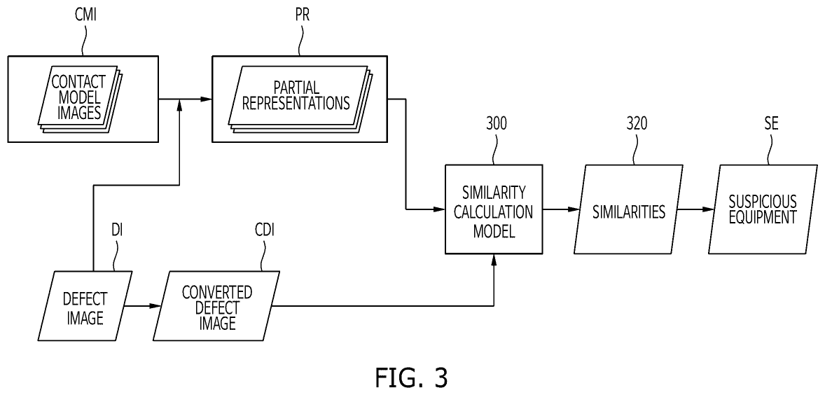

FIG. 3 is a block diagram of an example of a method for estimating a cause of a defect in a semiconductor wafer according to another aspect. Most of the above description of the method for determining the suspicious equipment SE described with reference to FIG. 2 may be equally/similarly applicable to the example of FIG. 3. Hereinbelow, redundant description will be omitted and additions/modifications will be mainly described.

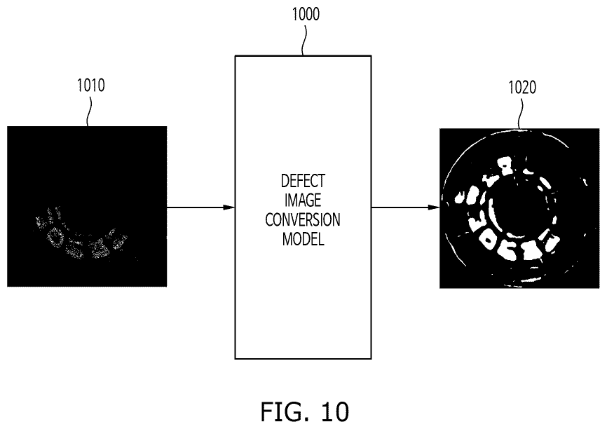

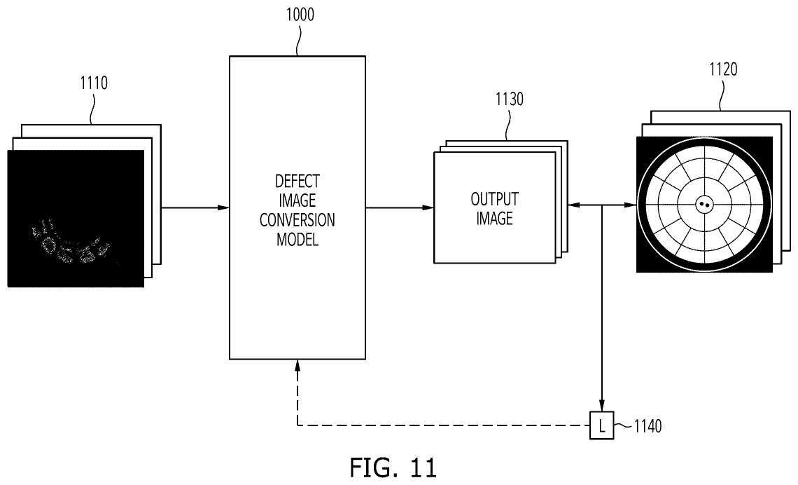

The defect cause estimation device may convert the defect information included in the defect image DI into a similar form as the contact model image CMI, thereby generating a converted defect image DI. For example, the converted defect image DI may be generated by converting the defect information represented in the form of dots in the defect image DI into a form of a plane. A detailed example of the method for generating the converted defect image DI will be described below with reference to FIGS. 10 and 11.

The defect cause estimation device may determine, from among the pieces of manufacturing equipment, suspicious equipment SE estimated to have caused the defect on the target wafer by comparing the partial representation PR of each contact model image CMI with the converted defect image DI. For example, the defect cause estimation device may calculate similarities 320 between the partial representation PR of each of the contact model images CMI and the converted defect image DI using the similarity calculation model 300, and determine the suspicious equipment SE based on the calculated similarities 320.

According to some aspects, improved estimation accuracy can be provided by transforming the form of the defect information included in the defect image DI to be similar to that of the information on the contact surface included in the contact model images CMI and by using the result for the estimation of the suspicious equipment SE.

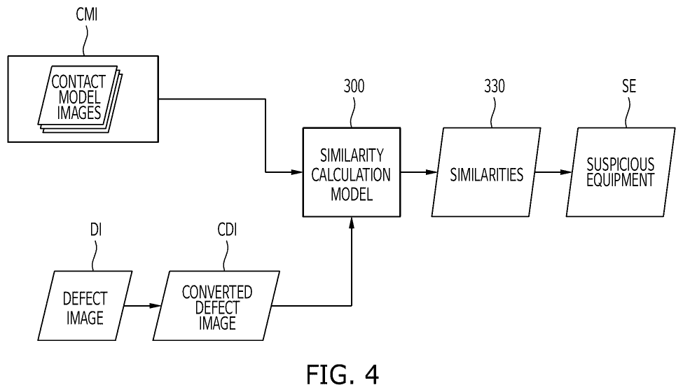

FIG. 4 is a block diagram of an example of a method for estimating a cause of a defect in a semiconductor wafer. Most of the above description of the method for determining the suspicious equipment SE with reference to FIGS. 2 and 3 may be equally/similarly applicable to an example of FIG. 4. Hereinbelow, redundant description will be omitted and additions/modifications will be mainly described.

The defect cause estimation device may determine, from among pieces of manufacturing equipment, suspicious equipment SE estimated to have caused the defect in a target wafer by comparing each of the contact model images CMI with the converted defect image DI. For example, the defect cause estimation device may calculate similarities 330 between each of the contact model images CMI and the converted defect image DI using the similarity calculation model 300 and determine the suspicious equipment SE based on the calculated similarities 330.

FIG. 5 is a diagram illustrating an example of contact model images 510, 520, 530, and 540. The contact model images 510, 520, 530, and 540 may include the information on the contact surfaces between the pieces of manufacturing equipment and the wafer. For example, the contact model images 510, 520, 530, and 540 may include information on parts of the pieces of manufacturing equipment in contact with the backside of the wafer.

The contact model images 510, 520, 530, and 540 may be generated by displaying the parts of the pieces of manufacturing equipment in contact with the wafer (e.g., with the backside of the wafer) based on drawings or photographs of the pieces of manufacturing equipment, or may be generated by reversely estimating the contact surfaces with the wafer based on the actual defect image, but the aspects are not limited thereto, and the contact model images 510, 520, 530, and 540 may be generated with any method.

Each of the contact model images 510, 520, 530, and 540 may correspond to one (or a part thereof) of the pieces of manufacturing equipment. For example, a first contact model image 510, a second contact model image 520, a third contact model image 530, and a fourth contact model image 540 may correspond to a first piece of manufacturing equipment, a second piece of manufacturing equipment, a third piece of manufacturing equipment, and a fourth piece of manufacturing equipment (or a part thereof), respectively.

Each pixel of each of the contact model images 510, 520, 530, and 540 may represent a first value corresponding to when a corresponding point of the manufacturing equipment associated with the contact model image 510, 520, 530, and 540 is not in contact with the backside of the wafer during the process, or a second value corresponding to when the corresponding point is in contact with the backside of the wafer. For example, each pixel of the first contact model image 510 may have the first value when the corresponding point of the first manufacturing equipment is not in contact with a backside of the wafer during the process, and a second value when the corresponding point is in contact with the backside of the wafer.

FIG. 6 is a diagram illustrating an example of defect images 610, 620, 630, and 640. The defect images 610, 620, 630, and 640 may include defect information of the target wafer. For example, the defect images 610, 620, 630, and 640 may be images in which the defect information of the backside of the target wafer is represented in the form of dots. The defect images 610, 620, 630, and 640 may be generated based on an inspection result generated by an optical scanning-based inspection device, but aspects are not limited thereto, and the defect images 610, 620, 630, and 640 may be generated by any method.

Each pixel of the defect images 610, 620, 630, and 640 may represent a value between a first value and a second value according to a degree of defect at the corresponding point of the target wafer. For example, each pixel of the defect images 610, 620, 630, and 640 may have the first value when there is no defect at the corresponding point of the target wafer, the second value when there is a maximum degree of defect at the corresponding point of the target wafer, and a value greater than the first value and less than the second value depending on the defect degree when the degree of defect at the corresponding point of the target wafer is less than the maximum.

FIG. 7 is a diagram of an example of a method for generating partial representations 730 of contact model images 710.

Referring to FIG. 7, the defect cause estimation device may generate the partial representation 730 of each of the contact model images 710 by extracting parts associated with defect information included in a defect image 720 of each of the contact model images 710 based on the contact model images 710 and the defect image 720.

For example, first, the defect cause estimation device may define a plurality of contact regions (a01 to a30) within the contact model images 710 using a contour extraction method for each of the contact model images 710. As a specific example, as illustrated in FIGS. 7, 30 contact regions (a01 to a30) may be defined by extracting the contour of the contact model images 710.

The defect cause estimation device may calculate similarities between the plurality of contact regions (a01 to a30) and parts of the defect image 720 corresponding to each of the plurality of contact regions (a01 to a30). Any similarity calculation method (e.g., a pixel-by-pixel comparison-based similarity method, etc.) may be used for the similarity calculation method. For example, the defect cause estimation device may calculate the similarities between the 30 contact regions (a01 to a30) of the contact model image 710 and the parts of the defect image 720 corresponding to each of the contact regions (a01 to a30). Specifically, the defect cause estimation device may calculate the similarity between a first contact region a01 of the contact model image 710 and a part of the defect image 720 corresponding to the first contact region a01. Further, the defect cause estimation device may calculate the similarity between a second contact region a02 of the contact model image 710 and a part of the defect image 720 corresponding to the second contact region a02. In this way, the defect cause estimation device may calculate the similarities (e.g., a total of 30 similarities in the example of FIG. 7) between the 30 contact regions (a01 to a30) of the contact model image 710 and the parts of the defect image 720 corresponding to each of the contact regions (a01 to a30).

The defect cause estimation device may extract, from among the plurality of contact regions (a01 to a30) of the contact model image, regions a08, a11, a13 to a17 having similarities greater than or equal to a predetermined threshold. For example, in the example of FIG. 7, the defect cause estimation device may extract the 8th, 11th, and 13th to 17th contact regions (a08, a11, a13 to a17) with similarities greater than or equal to the predetermined threshold from among the plurality of contact regions (a01 to a30) of the contact model image. An image including the contact regions (a08, a11, a13 to a17) extracted as described above may be the partial representation 730 of the contact model image.

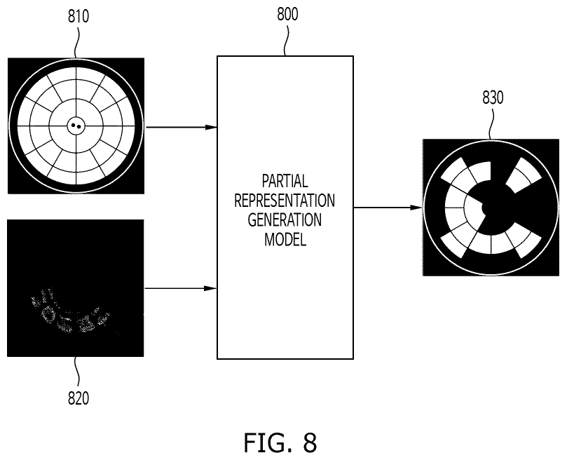

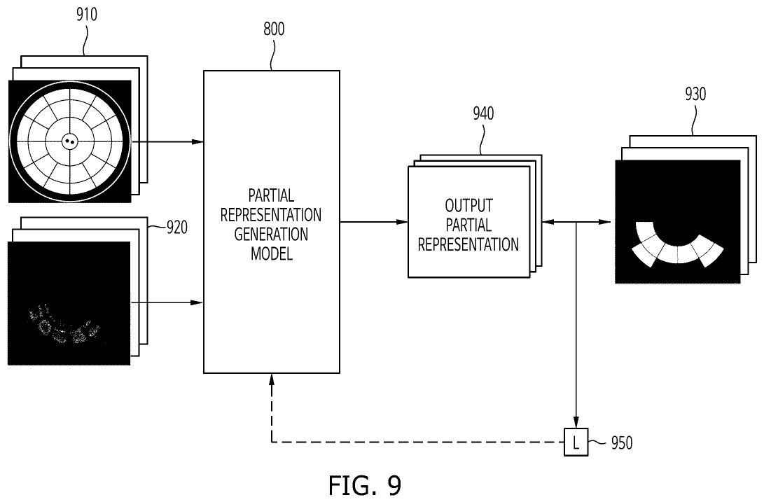

FIGS. 8 and 9 are example diagrams of a method for generating partial representations 830 of contact model images 810.

Referring to FIG. 8, the defect cause estimation device may generate the partial representations 830 of the contact model images 810 based on the contact model images 810 and a defect image 820 by using a partial representation generation model 800. The defect cause estimation device may be a machine learning model configured to receive the contact model images 810 and the defect image 820 as input and output the partial representations 830 of the contact model image 810 of the input contact model images 810 that represents the part associated with the defect information included in the input defect image 820. For example, the partial representation generation model 800 may be a generative machine learning model such as a Generative Adversarial Networks (GAN)-based model, an autoencoder-based model, and a transformer-based model, etc., but aspects are not limited thereto. The defect cause estimation device may generate the partial representation 830 of each contact model image 810 by inputting each contact model image 810 and the defect image 820 to the partial representation generation model 800.

Referring to FIG. 9, the partial representation generation model 800 may be a machine learning model trained based on a training data set including training contact model images 910, training defect images 920, and ground truth partial representations 930 corresponding to the training contact model images 910 and the training defect images 920. Some of the training data included in the training data set may be generated through data augmentation. For example, new training contact model images 910 and/or ground truth partial representations 930 may be generated by applying various modifications (e.g., partial extraction, partial deletion, rotation, cropping, noise addition, etc.) to the training contact model image 910. Further, the training defect images 920 may be generated by performing random sampling on the ground truth partial representations 930.

In the training process, the partial representation generation model 800 may receive the training contact model image 910 and the training defect image 920 as input and output partial representations 940. Weights of the partial representation generation model 800 may be updated based on a loss 950 calculated based on the output partial representations 940 and the ground truth partial representations 930. Through this training process, the partial representation generation model 800 may be trained.

The process of generating the training data and training the partial representation generation model 800 may be performed by the defect cause estimation device and/or an external device.

FIGS. 10 and 11 are example diagrams of a method for generating a converted defect image 1020.

Referring to FIG. 10, the defect cause estimation device may generate the converted defect image 1020 by converting the defect information included in a defect image 1010 into a form similar to contact model images. For example, the converted defect image 1020 may be generated by converting defect information represented in the defect image 1010 in the form of dots into a form of a plane. For example, conversion into the form of a plane may include conversion into one or more two-dimensional shapes, e.g., solid and/or closed two-dimensional shapes.

The defect cause estimation device may generate the defect image 1020 which is converted based on the defect image 1010, by using a defect image conversion model 1000. The defect image conversion model 1000 may be a machine learning model configured to receive the defect image 1010 as input and convert the input defect image 1010 into a form similar to the contact model images (e.g., convert the defect information represented in the form of dots into a form of a plane) and output the result. For example, the defect image conversion model 1000 may be a generative machine learning model such as a GAN-based model, an autoencoder-based model, a transformer-based model, etc., but aspects are not limited thereto. The defect cause estimation device may generate the converted defect image 1020 by inputting the defect image 1010 to the defect image conversion model 1000.

Referring to FIG. 11, the defect image conversion model 1000 may be a machine learning model trained based on a training data set including training defect images 1110 and ground truth contact model images 1120 corresponding to the training defect images 1110. Some of the training data included in the training data set may be generated through data augmentation. For example, the training defect images 1110 may be generated by performing various modifications (e.g., partial extraction, partial deletion, rotation, cropping, noise addition, etc.) and random sampling on the ground truth contact model image 1120.

In the training process, the defect image conversion model 1000 may receive the training defect image 1110 as input and output an image 1130. Weights of the defect image conversion model 1000 may be updated based on a loss 1140 calculated based on the output image 1130 and the ground truth contact model image 1120. Through this training process, the defect image conversion model 1000 may be trained.

The process of generating the training data and training the defect image conversion model 1000 may be performed by the defect cause estimation device and/or an external device.

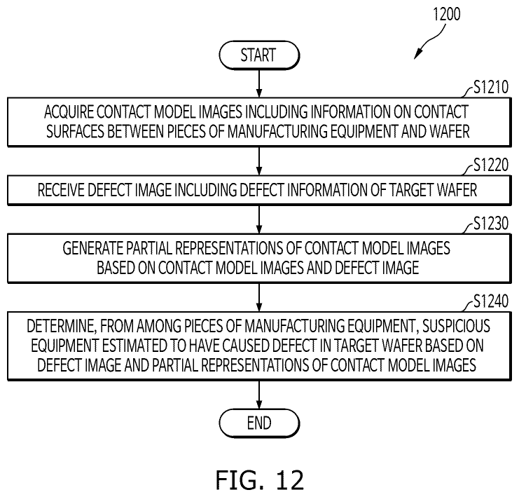

FIG. 12 is a flowchart of an example of a method 1200 for estimating a cause of a defect in a semiconductor wafer. The method 1200 may be performed by a processor (e.g., at least one processor of the defect cause estimation device).

The processor may acquire contact model images including information on contact surfaces between the pieces of manufacturing equipment and the wafer, at S1210. For example, the contact model images may include information on parts of the pieces of manufacturing equipment in contact with the backside of the wafer. As a specific example, each pixel of each of the contact model images may represent a first value corresponding to when a corresponding point of the manufacturing equipment associated with the contact model image is not in contact with the backside of the wafer during the process, or a second value corresponding to when the corresponding point is in contact with the backside of the wafer.

Further, the processor may receive a defect image including defect information of the target wafer, at S1220. For example, the defect image may be an image including defect information of the backside of the target wafer. As a specific example, each pixel of the defect image may represent a value between the first value and the second value according to a degree of defect at the corresponding point of the target wafer.

The processor may generate a partial representation of each contact model image based on the contact model images and the defect image, at S1230. The partial representation of the contact model image may be an image representing a part of the information on the contact surface included in the contact model image that is associated with the defect information included in the defect image.

The processor may generate a partial representation of each contact model image by extracting a part associated with defect information included in the defect image of each contact model image based on the contact model images and the defect image. For example, using a contour extraction method, the processor may define, for each of the contact model images, a plurality of contact regions within the contact model images. By calculating the similarities between the plurality of contact regions and the parts of the defect images corresponding to each of the plurality of contact regions and extracting regions with the similarities greater than or equal to a predetermined threshold, a partial representation may be generated.

Additionally or alternatively, using the partial representation generation model, the processor may generate partial representations of the contact model images based on the contact model images and the defect image. The partial representation generation model may be a machine learning model trained based on a training contact model image, a training defect image, and a ground truth partial representation corresponding to the training contact model image and the training defect image.

Based on the defect image and the partial representations of the contact model images, the processor may determine, from among the pieces of manufacturing equipment, suspicious equipment estimated to have caused the defect on the target wafer, at S1240. For example, the processor may calculate similarities between the partial representation of each of the contact model images and the defect image. The processor may determine the suspicious equipment based on the calculated similarities. As a specific example, one of the pieces of manufacturing equipment that is associated with one contact model image with the highest similarity to the defect image of contact model images may be determined as the suspicious equipment. As another specific example, pieces of manufacturing equipment associated with the contact model images that are within a predetermined ranking among the contact model images based on their similarities to the defect image may be determined as a suspicious equipment group. For the manufacturing equipment determined as the suspicious equipment, additional investigation and analysis for resolving the cause of the defect may be performed through the defect cause estimation device and/or an external device.

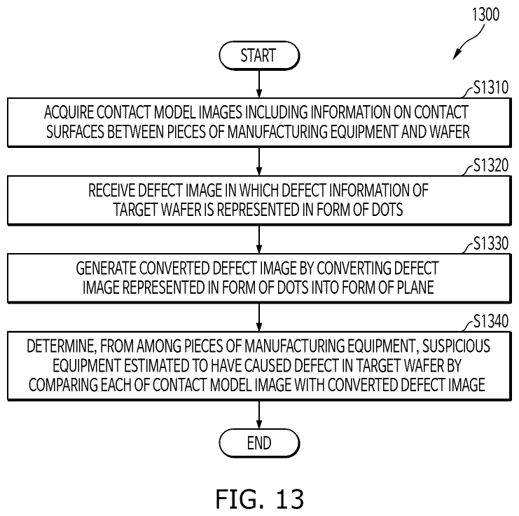

FIG. 13 is a flowchart of an example of a method 1300 for estimating a cause of a defect in a semiconductor wafer. The method 1300 may be performed by a processor (e.g., at least one processor of the defect cause estimation device). The elements or operations already described above with reference to FIG. 12 will not be described or briefly described.

The processor may acquire contact model images including information on contact surfaces between the pieces of manufacturing equipment and the wafer, at S1310. For example, the contact model images may include information on parts of the pieces of manufacturing equipment in contact with the backside of the wafer. As a specific example, each pixel of each of the contact model images may represent a first value corresponding to when a corresponding point of the manufacturing equipment associated with the contact model image is not in contact with the backside of the wafer during the process, or a second value corresponding to when the corresponding point is in contact with the backside of the wafer.

Further, the processor may receive a defect image in which defect information of the target wafer is represented in the form of dots, at S1320. For example, the defect image may be an image in which the defect information of the backside of the target wafer is represented in the form of dots. As a specific example, each pixel of the defect image may represent a value between the first value and the second value according to a degree of defect at the corresponding point of the backside of the target wafer.

The processor may generate a converted defect image by converting the defect information represented in the form of dots in the defect image into a form of a plane, at S1330. For example, the processor may generate a defect image converted based on the defect image by using a defect image conversion model. The defect image conversion model may be a machine learning model trained based on a training defect image and a ground truth contact model image corresponding to the training defect image.

By comparing each of the contact model images with the converted defect image, the processor may determine, from among the pieces of manufacturing equipment, suspicious equipment estimated to have caused the defect on the target wafer, at S1340. For example, the processor may calculate similarities between each of the contact model images and the converted defect image. The processor may determine the suspicious equipment based on the calculated similarities.

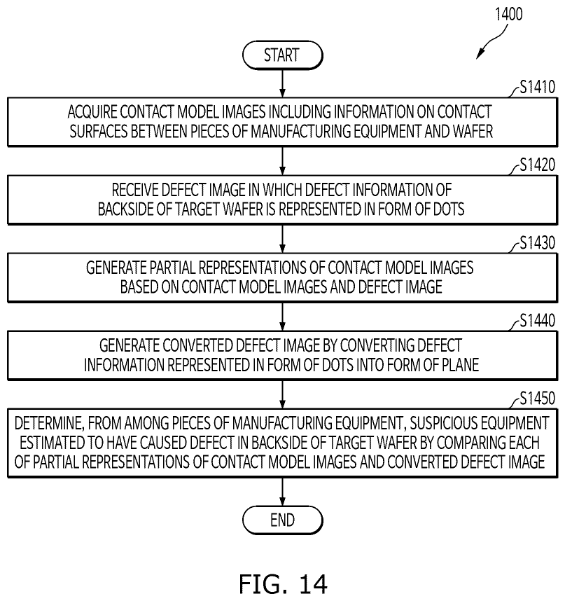

FIG. 14 is a flowchart of an example of a method for estimating a cause of a defect in a semiconductor wafer. The method 1400 may be performed by a processor (e.g., at least one processor of the defect cause estimation device). The elements or operations already described above with reference to FIGS. 12 and 13 will not be described or briefly described. The processor may acquire contact model images including information on contact surfaces between the pieces of manufacturing equipment and the backside of the wafer, at S1410. Further, the processor may receive a defect image in which defect information of the backside of the target wafer is represented in the form of dots, at S1420.

The processor may generate a partial representation of each contact model image based on the contact model images and the defect image, at S1430. The partial representation of the contact model image may be an image representing a part of the information on the contact surface included in the contact model image that is associated with the defect information included in the defect image. Further, the processor may generate a converted defect image by converting the defect information represented in the form of dots in the defect image into a form of a plane, at S1440.

By comparing each of the partial representations of the contact model images with the converted defect image, the processor may determine suspicious equipment estimated to have caused the defect in the backside of the target wafer of the pieces of manufacturing equipment at S1450. For example, the processor may calculate similarities between each of the partial representations of the contact model images and the converted defect image. The processor may determine the suspicious equipment based on the calculated similarities.

The flowcharts and the description described above with reference to FIGS. 12 to 14 are merely examples, and may be implemented differently in some aspects. For example, in some aspects, the order of respective operations may be changed, some of the operations may be repeatedly performed, some may be omitted, or some may be added.

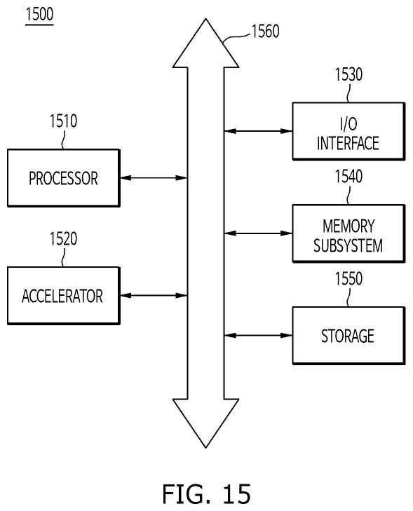

FIG. 15 is a block diagram of an example of a defect cause estimation system.

Referring to FIG. 15, the defect cause estimation system 1500 may include a processor 1510, an accelerator 1520, an input/output interface 1530, a memory subsystem 1540, a storage 1550, and a bus 1560. The processor 1510 and the memory subsystem 1540 of FIG. 15 may respectively correspond to the processor 210 and the memory 220 of FIG. 1, and the overlapping description thereof will be omitted.

The processor 1510, the accelerator 1520, the input/output interface 1530, the memory subsystem 1540, and the storage 1550 may communicate with each other through the bus 1560. In some aspects, the defect cause estimation system 1500 may be a system-on-chip (SoC) in which components are implemented in one chip, and the storage 1550 may be outside of the system-on-chip. In some aspects, at least one of the components illustrated in FIG. 15 may be omitted from the defect cause estimation system 1500.

The processor 1510 may control the operations described above with reference to the drawings of the defect cause estimation system 1500 at the highest level, and may control other components of the defect cause estimation system 1500.

In some aspects, the processor 1510 may include two or more processing cores. As described above with reference to the drawings, the processor 1510 may process various steps necessary for the operation of the defect cause estimation system 1500 to determine the suspicious equipment estimated to have caused the defect in the target wafer.

The accelerator 1520 may be designed to perform a designated function at a high speed. For example, the accelerator 1520 may process data received from the memory subsystem 1540 and provide the resultant data to the memory subsystem 1540.

The input/output interface 1530 may receive an input from the outside of the defect cause estimation system 1500 and provide an interface for providing an output to the outside of the defect cause estimation system 1500. For example, the defect cause estimation system 1500 may receive a reference similarity (such as a predetermined threshold) or a partial representation generation model, which are used for generating the contact model images and the partial representations of the contact model images, from the outside through the input/output interface 1530. Further, the defect cause estimation system 1500 may receive a defect image from the outside through the input/output interface 1530. However, aspects are not limited thereto. For example, at least some of the data described above may be provided within the defect cause estimation system 1500.

The memory subsystem 1540 may be accessible to other components connected to the bus 1560. In some aspects, the memory subsystem 1540 may include volatile memory such as DRAM and SRAM, or may include non-volatile memory such as flash memory or resistive random access memory (RRAM). Further, in some aspects, the memory subsystem 1540 may provide an interface to the storage 1550. The storage 1550 may be a storage medium which does not lose data even when power is interrupted. For example, the storage 1550 may include a semiconductor memory device such as a non-volatile memory, or may include any storage medium such as a magnetic card/disk or an optical card/disk. In some aspects, the contact model images may be stored in the memory subsystem 1540 or the storage 1550. Further, in some aspects, the various aforementioned data necessary for determining the suspicious equipment may be stored in the memory subsystem 1540 or the storage 1550.

The bus 1560 may operate based on one of various bus protocols. The various bus protocols described above may include at least one of Advanced Microcontroller Bus Architecture (AMBA) protocol, Universal Serial Bus (USB) protocol, Multi-Media Card (MMC) protocol, PCI-Express (PCI-E) protocol, Advanced Technology Attachment (ATA) protocol, Serial-ATA protocol, Parallel-ATA protocol, Small Computer Small Interface (SCSI) protocol, Enhanced Small Disk Interface (ESDI) protocol, Integrated Drive Electronics (IDE) protocol, Mobile Industry Processor Interface (MIPI) protocol, Universal Flash Storage (UFS) protocol, etc.

As described above, example aspects are disclosed in the drawings and the description. Although aspects have been described using specific terms in the present description, these terms are used only for the purpose of explaining the technical idea of the present disclosure and not to limit the meaning or the scope of the present disclosure described in the claims. Therefore, those with ordinary knowledge in the art will understand that various modifications and other equivalent aspects are possible. Therefore, the true technical protection scope of the present disclosure should be determined by the technical idea of the appended claims.

1. A method for identifying a cause of a defect in a semiconductor wafer, the method being performed by at least one processor and comprising:
obtaining a plurality of contact model images including information of a plurality of contact surfaces between a plurality of manufacturing equipment and wafers;
obtaining a defect image including defect information of a target wafer;
generating, based on the plurality of contact model images and the defect image, a plurality of partial representations of the plurality of contact model images, wherein each of the plurality of partial representations represents a portion of a respective contact model image of the plurality of contact model images, and wherein the portion is associated with the defect information; and
determining, from among the plurality of manufacturing equipment, first equipment to have caused a defect in the target wafer, based on the defect image and the plurality of partial representations of the plurality of contact model images.

2. The method of claim 1, wherein the defect image includes defect information of a backside of the target wafer.

3. The method of claim 1, wherein the plurality of contact model images include information on contact between the plurality of manufacturing equipment and backsides of the wafers.

4. The method of claim 1, wherein generating the plurality of partial representations of the plurality of contact model images includes extracting respective portions of the plurality of contact model images, wherein the respective portions are associated with the defect information.

5. The method of claim 4, wherein extracting the respective portions of the plurality of contact model images includes, for each contact model image of the plurality of contact model images:
defining a plurality of contact regions within the contact model image using a contour extraction method;
calculating a plurality of similarities between the plurality of contact regions and a plurality of corresponding portions of the defect image; and
extracting a plurality of regions of the plurality of contact regions, each region of the plurality of regions having a similarity to the corresponding portion of the defect image that is greater than or equal to a predetermined threshold.

6. The method of claim 1, wherein generating the plurality of partial representations of the plurality of contact model images includes generating the plurality of partial representations based on the plurality of contact model images and the defect image using a partial representation generation model.

7. The method of claim 6, wherein the partial representation generation model includes a machine learning model,
wherein the machine learning model is trained based on a training contact model image, a training defect image, and a ground truth partial representation corresponding to the training contact model image and the training defect image.

8. The method of claim 1, wherein:
the defect image includes the defect information of the target wafer represented as a plurality of dots,
the method includes generating a converted defect image by converting the defect information represented as the plurality of dots into a representation as one or more two-dimensional shapes, and
determining the first equipment includes determining the first equipment by comparing each partial representation of the plurality of partial representations with the converted defect image.

9. The method of claim 8, wherein:
generating the converted defect image includes generating the converted defect image based on the defect image using a defect image conversion model,
the defect image conversion model includes a machine learning model, and
the machine learning model is trained based on a training defect image and a ground truth contact model image corresponding to the training defect image.

10. The method of claim 1, wherein determining the first equipment comprises:
calculating a plurality of respective similarities between each partial representation of the plurality of partial representations and the defect image; and
determining the first equipment based on the calculated plurality of respective similarities.

11. The method of claim 10, wherein determining the first equipment based on the calculated plurality of respective similarities includes determining, as the first equipment, one of the plurality of manufacturing equipment associated with a contact model image, of the plurality of contact model images, that has a partial representation, of the plurality of partial representations, with a highest similarity to the defect image.

12. The method of claim 10, wherein determining the first equipment based on the calculated plurality of respective similarities includes determining, as a suspicious equipment group, at least two manufacturing equipment of the plurality of manufacturing equipment based on the calculated plurality of respective similarities,
wherein the at least two manufacturing equipment are associated with at least two contact model images within a predetermined ranking among the plurality of contact model images, the predetermined ranking based on the plurality of respective similarities.

13. The method of claim 1, wherein each pixel of each contact model image of the plurality of contact model images represents a first value or a second value, the first value indicating that a corresponding point of manufacturing equipment associated with the contact model image is separated from a backside of a wafer during a process, the second value indicating that the corresponding point contacts the backside of the wafer.

14. The method of claim 1, wherein each pixel of the defect image represents a value indicating a degree of a defect at a corresponding point of the target wafer.

15. A method for identifying a cause of a defect in a semiconductor wafer, the method being performed by at least one processor and comprising:
obtaining a plurality of contact model images including information of a plurality of contact surfaces between a plurality of manufacturing equipment and wafers;
obtaining a defect image including defect information of a target wafer represented as a plurality of dots;
generating a converted defect image by converting the defect information represented as the plurality of dots into a representation as one or more two-dimensional shapes; and
determining, from the plurality of manufacturing equipment, first equipment to have caused a defect in the target wafer by comparing each contact model image of the plurality of contact model images with the converted defect image.

16. The method of claim 15, wherein:
generating the converted defect image includes generating the converted defect image based on the defect image using a defect image conversion model,
the defect image conversion model includes a machine learning model, and
the machine learning model is trained based on a training defect image and a ground truth contact model image corresponding to the training defect image.

17. The method of claim 15, wherein determining the first equipment comprises:
calculating a plurality of respective similarities between each contact model image of the plurality of contact model images and the converted defect image; and
determining the first equipment based on the calculated plurality of respective similarities.

18. The method of claim 15, wherein the defect image includes defect information of a backside of the target wafer.

19. The method of claim 15, wherein the plurality of contact model images include information on contact between the plurality of manufacturing equipment and backside of the wafers.

20. A method for identifying a cause of a defect in a semiconductor wafer, the method being performed by at least one processor and comprising:
obtaining a plurality of contact model images including information of a plurality of contact surfaces between a plurality of manufacturing equipment and backsides of wafers;
obtaining a defect image including defect information of a backside of a target wafer represented as a plurality of dots;
generating, based on the plurality of contact model images and the defect image, a plurality of partial representations of the plurality of contact model images, wherein each of the plurality of partial representations represents a portion of a respective contact model image of the plurality of contact model images, and wherein the portion is associated with the defect information;
generating a converted defect image by converting the defect information represented as the plurality of dots into a representation as one or more two-dimensional shapes; and
determining, from the plurality of manufacturing equipment, first equipment to have caused a defect in the backside of the target wafer based on comparing each partial representation of the plurality of partial representations with the converted defect image.
